(19) United States
(12) Patent Application Publication
(10) Pub. No.: US 2025/0203809 A1
(43) Pub. Date: Jun. 19, 2025

(54) APPARATUS FOR FLUID IMMERSION COOLING

(71) Applicant: CGG Services SAS, Massy (FR)

(72) Inventors: Laurent Clerc, Houston, TX (US); Jean-Yves Blanc, Massy (FR)

(73) Assignee: CGG Services SAS, Massy (FR)

(21) Appl. No.: 18/540,434

(22) Filed: Dec. 14, 2023

(51) Int. Cl. H05K 7/20

(52) U.S. Cl. CPC H05K 7/20272; H05K 7/20236; H05K 7/20263

(57) ABSTRACT

A device for cooling an electronic component in a cooling fluid immersion environment includes a heatsink, a casing, a micropump, and a first conduit. The heatsink is removably attached to the electronic component and includes baffles that direct the cooling fluid to flow over the electronic component. The cooling fluid absorbs heat from the electronic component. The casing includes an inlet orifice, an outlet orifice, and an internal volume containing the heatsink and the electronic component. The micropump actuates to forcefully direct the cooling fluid from an area surrounding the device, through the inlet orifice, through the series of baffles of the heatsink, and out of the outlet orifice of the casing. Further, the first conduit is connected to the micropump and directs the cooling fluid to the series of baffles of the heatsink within the internal volume of the casing.

### BACKGROUND

In general, electronic components generate heat while operating. This heat may, in turn, detrimentally impact the performance of the electronic components by increasing their electrical resistance, causing component burnout, or effecting similar forms of equipment failure. To alleviate the detrimental effects of the generated heat, it is becoming increasingly common to use a cooling fluid to absorb heat from the electronic components and redistribute the heat to a separate location away from the electronic components for further dissipation. Such a concept is found in immersion cooling systems in which an electronic component is submerged in a dynamic cooling fluid flow.

However, electronic components are generally interconnected by way of a circuit board containing electrically connective pathways, such that the electronic components are physically disposed adjacent to each other. Furthermore, it may be the case that only some of the electronic components (e.g., a Graphic Processing Unit (GPU)) of an electronic system may generate a substantial amount of heat, while other components (e.g., a data port) may generate a relatively nominal amount of heat. Thus, in such cases, it is desirable to direct the flow of the cooling fluid to specific electronic components generating a substantial heat load, rather than generally directing the cooling fluid flow over the entirety of the circuit board containing the electronic components.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

A device for cooling an electronic component in a cooling fluid immersion environment includes a heatsink, a casing, a micropump, and a first conduit. The heatsink is removably attached to the electronic component and includes baffles that direct the cooling fluid to flow over the electronic component, at which point the cooling fluid absorbs heat from the electronic component. The casing includes an inlet orifice, an outlet orifice, and an internal volume containing the heatsink and the electronic component. The micropump actuates to forcefully direct the cooling fluid from an area surrounding the device, through the inlet orifice, through the series of baffles of the heatsink, and out of the outlet orifice of the casing. Further, the first conduit is connected to the micropump and directs the cooling fluid to the series of baffles of the heatsink within the internal volume of the casing.

A method for cooling an electronic component in a cooling fluid immersion environment includes containing a heatsink, a micropump, a first conduit connected to the micropump, and the electronic component in an internal volume of a casing. The casing includes an inlet orifice and an outlet orifice. The micropump is actuated to forcefully direct the cooling fluid from an area surrounding the casing through the inlet orifice. The cooling fluid is directed, with a first conduit connected to the micropump, to a series of baffles of the heatsink within the internal volume of the casing. The method further includes absorbing heat from the electronic component with the cooling fluid, where the cooling fluid is directed to flow over the electronic component by the series of baffles of the heatsink removably attached to the electronic component. Further, the method includes directing the cooling fluid out of the casing with the outlet orifice.

Any combinations of the various embodiments and implementations disclosed herein can be used in a further embodiment, consistent with the disclosure. Other aspects and advantages of the claimed subject matter will be apparent from the following description and the claims.

### BRIEF DESCRIPTION OF DRAWINGS

Specific embodiments of the disclosed technology will now be described in detail with reference to the accompanying figures. Like elements in the various figures are denoted by like reference numerals for consistency. The sizes and relative positions of elements in the drawings are not necessarily drawn to scale. For example, the shapes of various elements and angles are not necessarily drawn to scale, and some of these elements may be arbitrarily enlarged and positioned to improve drawing legibility.

FIG. 1 depicts a device in accordance with one or more embodiments disclosed herein.

FIG. 2 depicts a device in accordance with one or more embodiments disclosed herein.

FIG. 3 depicts a device in accordance with one or more embodiments disclosed herein.

FIG. 4 depicts a device in accordance with one or more embodiments disclosed herein.

FIG. 5 depicts a device in accordance with one or more embodiments disclosed herein.

FIG. 6 depicts a method for cooling an electronic component in a cooling fluid immersion environment in accordance with one or more embodiments disclosed herein.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not intended to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements. Furthermore, while certain components are referred to in the singular to simplify discussion of embodiments of the invention, those skilled in the art will appreciate that any individual component (i.e., an electronic component) may be replaced with a multitude of components in advanced embodiments of the invention.

In addition, throughout the application, the terms “upper” and “lower” may be used to describe the position of an element of the invention. In this respect, the term “upper” denotes an element disposed above a corresponding “lower” element in a vertical direction, while the term “lower” conversely describes an element disposed below a corresponding “upper” element in the vertical direction. Similarly, the term “inner” refers to an orientation closer to a center of an object than a corresponding “outer” orientation.

In general, embodiments of the invention are directed towards an immersion cooling system including a casing built around a micropump that is connected by a conduit or manifold to a heatsink or similar hollow cooling structure. The heatsink rests on top of an electronic component that generates a relatively high heat load, or is otherwise desirable to cool. The casing has an internal volume designed to maximize the exchange of heat between the electronic component and a cooling fluid. All the components of the system are fully immersed in a tank or container that retains the cooling fluid, which may be a dielectric fluid as described herein. The system is configured to circulate the cooling fluid through the casing by way of the micropump, and a conduit is connected to the heatsink to deliver the cooling fluid out of the casing. Within the casing, the micropump is in a location where the fluid is coldest, and pumps the fluid through the inlet pipe to the heatsink, and subsequently the outlet pipe. A controller actuates the micropump based upon the cooling demand of the electronic component below the heatsink. Thus, the system is configured to specifically direct the dielectric cooling fluid to the electronic component(s) that benefit(s) from a reduction in their generated heat load.

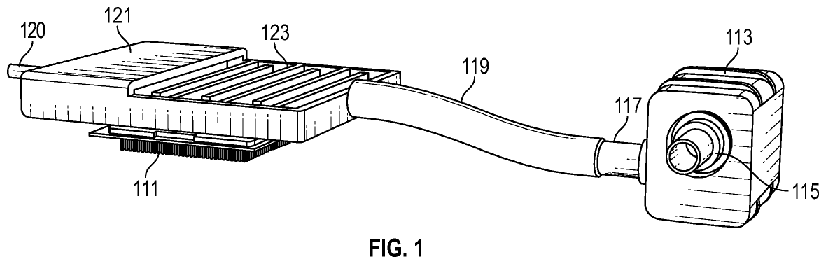

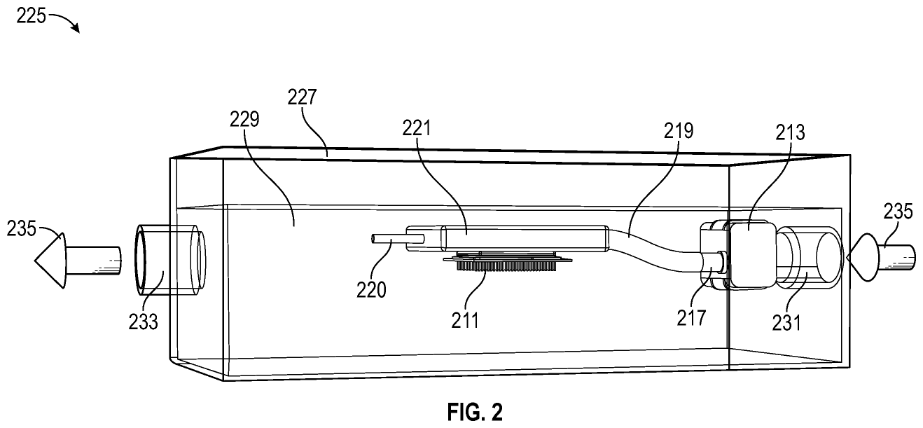

Initially, FIG. 1 depicts a view of an electronic component 111 that is to be cooled by a flow of a cooling fluid (e.g., FIG. 2) that is actuated by a micropump 113. By way of nonlimiting examples, the electronic component may be one or more computing hardware devices such as a microprocessor, a processing unit such as a Central Processing Unit (CPU) and/or a Graphics Processing Unit (GPU), a storage medium (e.g., a Hard Disk Drive (HDD), a Solid State Drive (SDD), or Random Access Memory (RAM)), and/or a communication device (e.g., ethernet, Wi-Fi, or other Local Area Network (LAN) or Wide Area Network (WAN) interconnects) such as a transceiver or networking card that serves to transmit and receive signals. However, the above description of the electronic component is not intended to limit the type of component to be cooled with the cooling fluid, and, thus, the electronic component 111 as described herein may further encompass various other electrically powered devices, equipment, and/or hardware known to a person having ordinary skill in the art.

An electronic component 111 generates a heat load as it operates as described above. If a sufficiently large heat load is developed by the electronic component 111, the electronic component 111 may be detrimentally impacted, such as the electronic component 111 becoming de-soldered, or hardware burnout occurring due to the large heat load. Furthermore, during extreme heat loads, an enclosure of the electronic component 111 (e.g., a processor housing) may melt, as electronic component 111 housings are typically formed of a plastic material. Thus, to avoid the above detrimental situations, it is advantageous to remove or reduce the heat load produced by the electronic component 111. While it is possible to reduce the heat load generated by an electronic component 111, such a process involves throttling the performance of the electronic component 111 to reduce its heat output, for example. Thus, under high stress environments, it may be desirable to remove the heat from the electronic component 111, rather than or in conjunction with reducing the heat output thereby.

In order to remove the heat from the electronic component 111 and as described above, a micropump 113 forcefully directs a fluid flow of a cooling liquid over the top of the electronic component 111 such that the cooling fluid transports the generated heat load away from the electronic component 111. Although not depicted in FIG. 1, components such as the micropump 113 and the electronic component 111 are submersed in the cooling fluid to form an immersion cooling environment. For its part, the micropump 113 includes an impeller (not shown) protected by a housing, and the impeller actuates in order to generate motion in a fluid that flows through the micropump 113. The micropump 113 further includes a micropump inlet 115 and a micropump outlet 117, which respectively form entrance and egress orifices for the cooling fluid flowing through the micropump 113. Alternatively, the micropump 113 may be replaced with a fan, propeller, or similar fluid agitation devices suitable for creating a controllable fluid flow.

The micropump 113 is connected, at its micropump outlet 117, to a conduit 119. The conduit 119 is a tube, pipe, or duct that serves to direct the fluid flow of the cooling fluid to a predetermined location that includes a heatsink 121. The conduit 119 may be formed of a metal such as stainless steel or brass, or alternatively of an elastomer such as polyurethane. In the case of FIG. 1, the predetermined location is a heatsink 121 that is removably attached to the electronic component 111, such that the conduit 119 provides fluid communication between the heatsink 121 and the micropump 113. To attach the conduit 119 to the heatsink 121 and the micropump outlet 117, each of the heatsink 121 and the micropump outlet 117 may be formed with internal threads. Similarly, the conduit 119 may have complimentary threaded ends such that the conduit 119 is screwed into the heatsink 121 and the micropump outlet 117. Alternatively, in cases where the conduit 119 is formed of an elastically deforming material, the conduit 119 may be adhered to the heatsink 121 and the micropump outlet 117 by compressive force provided by the conduit 119 itself. Other attachment methods may alternatively be used, such as adhesives or a pipe clamp, without departing from the nature of this disclosure.

During operation, the micropump 113 actuates to forcefully direct the cooling fluid through the conduit 119 and the heatsink 121. The heatsink 121 is formed as, for example, a rectangular metal frame with a series of internal baffles 123, shutters, or fins, which are solid protrusions of the heatsink 121 that serve to lengthen the fluid flow path of the cooling fluid as the cooling fluid flows over the electronic component 111. Each baffle 123 extends substantially across the length of the heatsink 121, leaving a small gap for the fluid to transfer into the next pass of baffles 123. In turn, the elongated fluid flow path created by the baffles 123 increases the amount of time for the cooling fluid to absorb heat from the electronic component 111.

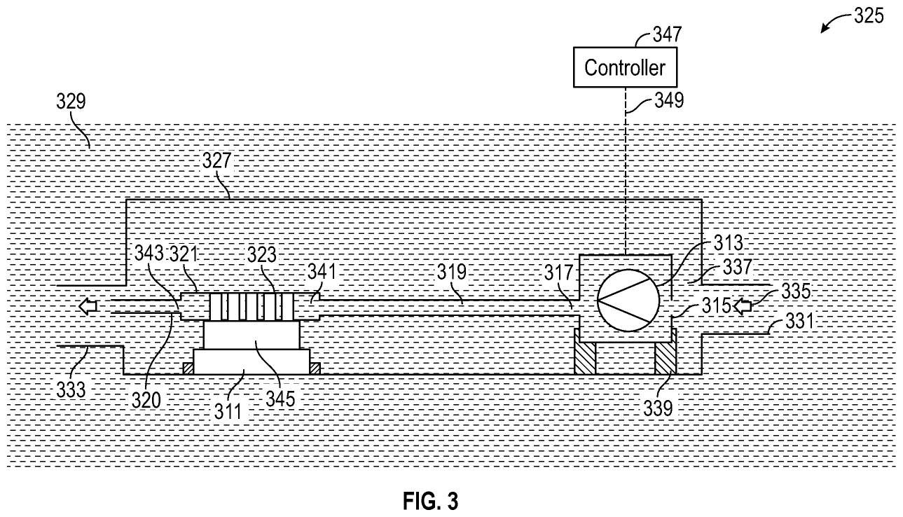

In addition, because the heatsink 121 is in contact with the electronic component 111, the heatsink 121 provides a thermal conduction mechanism that carries heat from the electronic component 111 to the baffles 123. In this way, the baffles 123 of the heatsink 121 further provide an increased surface area for the cooling fluid to absorb heat from the electronic component 111. More specifically, by virtue of the heatsink 121 being attached to the electronic component 111, the heat is conducted from the electronic component 111 to the heatsink 121, and dissipated into the cooling fluid by way of a convective thermal transfer process between the baffles 123 of the heatsink 121 and the cooling fluid. Accordingly, the increased surface area provided by the baffles 123 improves the efficiency of the heat absorption from the electronic component 111 by the cooling fluid (e.g., FIG. 3).

Once the cooling fluid (e.g., FIG. 3) has flowed through the heatsink 121, the fluid flows through a heatsink outlet (e.g., FIG. 3) into a second conduit 120, which is connected to the heatsink 121 at a first end and has a second, unattached free end. Alternatively, the second free end of the second conduit 120 may be formed with or fixed to a casing (e.g., FIG. 2) that surrounds the components of FIG. 1, such that the second conduit 120 delivers the cooling fluid out of the casing entirely. As the second conduit 120 receives the cooling fluid from the heatsink 121, which absorbs heat from the electronic component 111, the second conduit 120 serves to transfer the cooling fluid (and thus the heat absorbed by the cooling fluid) away from the electronic component 111. In low cost embodiments of the invention, a second conduit 120 may not be present, and the hot cooling fluid is expelled from the heatsink 121 directly. Overall, the components depicted in FIG. 1 thus serve to generate a fluid flow of a cooling fluid, and deliver the fluid flow over the electronic component 111 to remove heat therefrom prior to transferring the cooling fluid away from the electronic component 111.

Turning to FIG. 2, FIG. 2 depicts an immersion cooling device 225. Components of FIG. 2 sharing a same or similar name to components in FIG. 1 are generally imbued with the same or substantially similar properties or features unless discussed otherwise, but may naturally encompass or require additional functionality, structures, and/or materials not discussed above. In addition, similar components are denoted with similar component numberings. For example, FIG. 2 depicts that the immersion cooling device 225 includes an electronic component 211, which is similar or the same as the electronic component 111 of FIG. 1, as denoted by the final two numbers of both components being “11.” Although not discussed further below for the sake of brevity, components of FIGS. 3-5 are numbered in a similar manner.

As shown in FIG. 2, the immersion cooling device 225 includes a casing 227 that serves to protect and enshroud an electronic component 211, as well as the remaining components depicted in FIG. 1. As discussed above, the electronic component 211 comprises one or more electronic circuits and/or elements, and may include a Printed Circuit Board (PCB), for example, with heat generating electrical hardware formed thereon (e.g., multiple electronic components 211). The casing 227 is filled with a dielectric fluid 229 such as mineral oil, for example, that absorbs heat from the components enshrouded by the casing 227. In addition, the casing 227 may be formed of a material such as one or more plastics (e.g., polypropylene, polyethylene, polycarbonate, or equivalent polymers), or a metal such as aluminum, brass, steel, an alloy, or equivalent material. The casing 227 may be formed in two separate pieces that are fused or adhered together (e.g., by welding, using screws, bolts, or adhesives, etc.), or alternatively formed as a single, integrated component by processes such as injection molding or 3D printing.

The casing 227 is formed with a casing inlet 231 and a casing outlet 233, which serve as fluid communication orifices that direct the dielectric fluid 229 into and out of the casing 227, respectively. The casing inlet 231 and the casing outlet 233 may be formed at a same height of the casing 227, measured in a vertical direction that is orthogonal to a primary, or horizontal, extension direction of the casing 227. This causes the dielectric fluid 229 to flow along a fluid flow path 235 directly through the casing 227 without recirculating therein, which further facilitates the removal of heat from the electronic component 211. In addition, the casing inlet 231 and the casing outlet 233 are depicted in FIG. 2 as being located at opposite ends of the casing 227. However, the casing inlet 231 and the casing outlet 233 may be disposed at any suitable location of the casing 227 that does not disrupt or otherwise antagonize the flow of dielectric fluid 229 through the casing 227.

Within the casing 227, an upper face of the electronic component 211 is abutted against a heatsink 221, where the heatsink 221 is configured to lengthen the fluid flow path of a dielectric fluid 229 flowing over the electronic component 211. The heatsink 221 receives the dielectric fluid 229 from a conduit 219, which is a tube or pipe that connects a micropump outlet 217 of a micropump 213. The micropump 213 further serves to accelerate or otherwise imbue the dielectric fluid 229 with force from an internal impeller (not shown), for example. Initially, the micropump 213 draws the dielectric fluid 229 through the casing inlet 231 of the casing 227, such that a portion of the dielectric fluid 229 resides within the casing 227. The actuation of the micropump 213 subsequently causes the a portion of the dielectric fluid 229 to be forcefully directed through the conduit 219, the heatsink 221, a second conduit 220 connected to the heatsink 221, and out of the casing outlet 233. Thus, as the dielectric fluid 229 flows through the baffles 123 (e.g., FIG. 1) of the heatsink 221, the dielectric fluid 229 absorbs heat generated by the electronic component 211, and carries the heat out of the casing 227. In this way, the dielectric fluid 229 is configured to remove heat generated by the electronic component 211 out of the casing 227, and thus the immersion cooling device 225, entirely.

In order to further facilitate the removal of heat from the electronic component 211, the casing 227 itself is sized and shaped to tightly match the dimensions of the components contained therein (i.e., the electronic component 211, the micropump 213, the conduit 219, the second conduit 220, and the heatsink 221). Thus, as the dielectric fluid 229 is forcefully actuated by the micropump 213 in an internal volume of the casing 227, the casing 227 serves to concentrate and circulate the dielectric fluid 229 through the baffles 123 (e.g., FIG. 1) of the heatsink 221. More specifically, the casing 227 serves to direct a fluid flow path 235 of the dielectric fluid 229 to the micropump 213 with the casing inlet 231, and the micropump 213 causes the dielectric fluid 229 to be circulated through the baffles 123 of the heatsink 221 as discussed above.

Furthermore, the casing 227 may take additional forms as not described herein, or may be placed within a larger cooling system. For example, because the casing 227 is configured to surround an electronic component 211, the dimensions of the casing 227 may vary in design to accommodate the dimensions of the electronic component 211. In addition, the casing inlet 231 and the casing outlet 233 may also vary in design according to the geometry of a particular electronic component 211, or similar design considerations. By way of example, the casing inlet 231 and/or the casing outlet 233 may include a series of orifices, rather than a single orifice. Similarly, the casing inlet 231 and/or the casing outlet 233 may alternatively be formed as cutouts of the casing 227, rather than extrusions as depicted in FIG. 2. As a general design principle, however, the casing inlet 231 and the casing outlet 233 are positioned such that their location does not antagonize the flow of dielectric fluid 229 through the casing 227 (and the micropump 213, more specifically). That is, the casing inlet 231 and an inlet of the micropump 213 (e.g., micropump inlet 115 as depicted in FIG. 1) are positioned where the dielectric fluid 229 is relatively cool, and the casing outlet 233 is positioned to dispense hot dielectric fluid 229 away from the electronic component 211.

Turning to FIG. 3, FIG. 3 depicts an immersion cooling device 325 including a casing 327 in accordance with one or more embodiments of the invention as described herein. As shown in FIG. 3, and similar to FIGS. 1 and 2, the casing 327 is configured with a casing inlet 331 and a casing outlet 333 that serve to deliver a dielectric fluid 329 into and out of the internal volume of the casing 327. The casing 327 is both surrounded by and filled with a dielectric fluid 329, such that the dielectric fluid 329 flows into the casing 327 from a volume of the dielectric fluid 329 external to the casing 227, and returns to the same external volume of dielectric fluid 329. The dielectric fluid 329 may thus be contained in a container or system that also houses the casing 227, which is not depicted in FIG. 3.

Within the casing 327, a micropump 313 is disposed adjacent to the casing inlet 331, and serves to generate a fluid flow of the dielectric fluid 329 within the casing 327. However, and as depicted in FIG. 3, the micropump 313 may be positioned at a specified distance from the casing inlet 331, such that a gap 337 exists between the micropump 313 and the casing inlet 331. The gap 337 allows the dielectric fluid 329 to flow along a fluid flow path 335 from the casing inlet 331 into the internal volume of the casing 327 without also entering into the micropump 313. Thus, a portion of the dielectric fluid 329 is disposed surrounding the remaining components of the immersion cooling device 325 within the casing 327, such as the micropump 313, a heatsink 321, and an electronic component 311. This surrounding portion of the dielectric fluid 329 serves to further diffuse heat throughout the casing 327, as the dielectric fluid 329 has better thermal conduction properties than the air that would otherwise surround the components within the casing 327. In this way, the gap 337 further aids in reducing the temperature of the electronic component 311 by distributing heat away from the portions of the electronic component 311 not covered by the heatsink 321. The gap 337 has a width determined as a function of the design constraints of the immersion cooling device 325, and may be formed according to constraints such as the volume of the casing 327 that is void of elements, the amount of heat generated by a particular electronic component 311, or similar constraints.

The position of the micropump 313, and thus the creation of the gap 337, is facilitated by a series of positioning protrusions 339. The positioning protrusions 339 are integrally formed projections of the casing 327 that are shaped to accommodate and retain the position of a particular element of the immersion cooling device 325. For example, and as depicted in FIG. 3, the micropump 313 and the electronic component 311 are each retained in a horizontal direction by positioning protrusions 339, where the positioning protrusions 339 are sized and shaped to accommodate their associated element. To this end, because the electronic component 311 is depicted as abutting against the casing 327 in FIG. 3, the positioning protrusions 339 that retain the electronic component 311 are formed as cylindrical or rectangular pegs that extend upwards from the casing 327 to abut against the sides of the electronic component 311.

Similarly, the positioning protrusions 339 that retain the micropump 313 are formed as rectangular pegs with a cutout, or shelf, that maintains the lateral position of the micropump 313 within the casing 327. In this way, the positioning protrusions 339 also serve to adjust the height of the micropump 313 such that a micropump inlet 315 of the micropump 313 is positioned at a same height as the casing inlet 331 of the casing 327, which maximizes the efficiency of the immersion cooling device 325 by reducing the fluid flow path length between the casing inlet 331 and the micropump inlet 315. In alternative embodiments of the invention, the micropump 313 may be integrally formed with the electronic component electronic component 311, or connected thereto. For example, the micropump 313 may be connected to and powered by power pins or a power header (not shown) of the electronic component 311, where the electronic component 311 is embodied as a blade or rack server. In addition, the polarity of the micropump 313 may be switched, for example by reversing the order of the power pins, in order to have the micropump 313 pull dielectric fluid 329 through the casing 327 rather than pushing the dielectric fluid 329 therethrough.

Once the dielectric fluid 329 has been drawn through the micropump inlet 315, the micropump 313 pushes the dielectric fluid 329 through a micropump outlet 317 into a conduit 319. The micropump 313 is connected to a controller 347 by way of a data cable 349, or wire, where the controller 347 issues operating commands to the micropump 313 that instruct the micropump 313 to initiate, re-initiate, or cease its actuation. Alternatively, the micropump 313 may be continuously powered by the electronic component 311, and the controller 347 removed from the immersion cooling device 325 to simplify the design thereof. The cable 349 is depicted in FIG. 3 as passing through an upper side of the casing 327, and, as such, the casing 327 may include a dedicated passthrough orifice (not shown) shaped to closely match the cross section of the data cable 349. Alternatively, the data cable 349 may be routed through the casing inlet 331 or the casing outlet 333 of the casing 327, which obviates the need for a dedicated passthrough orifice (not shown). Additional cables included in an immersion cooling device 325, such as a power or data cable (not shown) connected to the electronic component 311, may pass through or be routed into the casing 327 by similar methods without departing from the nature of this specification.

As described herein, the controller 347 may be embodied as a processor, a microcontroller, an integrated circuit, or similar logic processing components capable of forming and issuing the operating commands. To this end, the operating commands are issued by the controller 347 when a temperature of the location of the electronic component 311 and the heatsink 321 exceeds a predetermined temperature threshold that is determined by the manufacturer of the immersion cooling device 325. The temperature of the location of the electronic component 311 may be provided by the electronic component 311 itself by way of internal thermistors (not shown), which are resistors with a variable resistance dependent on the external temperature. Thus, the electronic component 311 may determine its temperature based upon the resistance generated by the thermistors (not shown), and provide the temperature to the controller 347. By providing its temperature to the controller 347, the electronic component 311 enables the controller 347 to issue operating commands based upon its own temperature.

The micropump inlet 315 and the micropump outlet 317 are through orifices of the micropump 313, and allow the dielectric fluid 329 to flow through the micropump 313 itself. Similarly, the conduit 319 is a tube or pipe that connects the micropump outlet 317 to the heatsink 321. The heatsink 321 is formed with a heatsink inlet 341 and a heatsink outlet 343, which are orifices formed in sidewalls of the heatsink inlet 341 that border a series of internal baffles 323. Once the dielectric fluid 329 has passed through the conduit 319, the dielectric fluid 329 flows through the heatsink inlet 341 and through the series of internal baffles 323. As shown in FIG. 3, the internal baffles 323 are formed as walls that direct the dielectric fluid 329 to flow in a winding manner through the internal volume of the heatsink 321. The heatsink 321 itself is thus an enclosed structure, aside from the heatsink inlet 341 and the heatsink outlet 343, such that backpressure of the dielectric fluid 329 developed by the micropump 313 forces the dielectric fluid 329 through the baffles 323 of the heatsink 321.

As depicted in FIG. 3, the heatsink 321 is removably attached to the electronic component 311 by way of a detachable mount 345. The detachable mount 345 may be embodied as an adhesive, such as thermal paste, that includes an adhesive base material such as an epoxy mixed with a thermally-conductive filler such as aluminum particles. Alternatively, the detachable mount 345 may comprise a structural element such as a bracket, clip, or clamp retained to the electronic component 311 and the heatsink 321 by way of screws, bolts, or similar structural mechanisms. Furthermore, the detachable mount 345 may, in one or more embodiments, comprise both an adhesive layer and a structural element in order to securely attach the heatsink 321 to the electronic component 311.

Once the dielectric fluid 329 has passed through the heatsink 321 and absorbed heat from the electronic component 311, the dielectric fluid 329 flows through a heatsink outlet 343 of the heatsink 321 and into a second conduit 320. The second conduit 320 is connected at one end to the heatsink 321, and may be connected by various methods appreciated by a person of ordinary skill in the art and as described above. The other end of the second conduit 320 floats freely within the casing 327, and delivers the dielectric fluid 329 from the heatsink 321 to the casing outlet 333 of the casing 327. From the casing outlet 333, the dielectric fluid 329 may be passively returned to the casing inlet 331 to begin a new cycle of circulating through the immersion cooling device 325. Alternatively, the dielectric fluid 329 may be passed to a second cooling device, such as a radiator, or transfer its heat to an external dedicated cooling circuit. In this way, the immersion cooling device 325 is configured to transfer a heat load (or a portion thereof) from the electronic component 311 out of the casing 327 entirely, allowing the electronic component 311 to operate at a lower temperature overall.

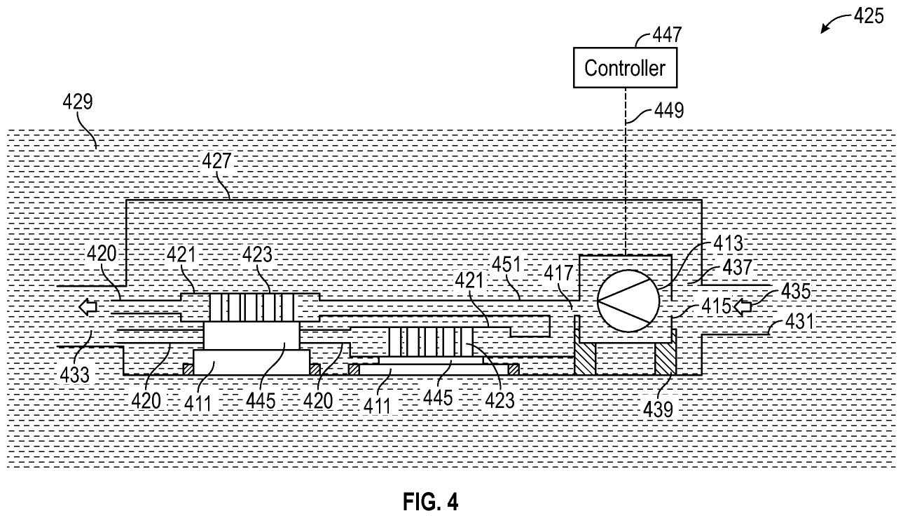

Turning to FIG. 4, FIG. 4 depicts one embodiment of an immersion cooling device 425 in accordance with one or more embodiments of the invention as described herein. Similar to the view of the immersion cooling device 325 presented in FIG. 3, FIG. 4 presents a side view of the immersion cooling device 425. The immersion cooling device 425 includes a micropump 413 with a micropump inlet 415 and a micropump outlet 417, where the micropump 413 is configured to actuate a dielectric fluid 429 through the immersion cooling device 425. The micropump 413 is connected to a controller 447 by way of a data cable 449, and the controller 447 issues operating commands to the micropump 413 that direct the micropump 413 to initiate or cease actuation, for example. Additionally, the micropump 413 is housed within a casing 427 of the immersion cooling device 425, where the casing 427 comprises an internal volume that concentrates and directs a volume of the dielectric fluid 429 towards the micropump 413.

More specifically, there is a gap 437 between a casing inlet 431 of the casing 427 and the micropump inlet 415 of the micropump 413 that introduces the dielectric fluid 429 into the internal volume formed by the casing 427, external to the micropump 413. The casing 427 is formed of a rigid material such as metal or plastic, and the casing 427 thus serves to retain the dielectric fluid 429 outside of the micropump 413 at a location surrounding a heat generating electronic component 411. The casing 427 further serves to generally redirect the dielectric fluid 429 towards the heat generating electronic component 411, as dielectric fluid 429 trying to flow away from the heat generating electronic component 411 will rebound off of the casing 427. In the same way, and because the micropump 413 is positioned within the casing 427, the casing 427 serves to also direct and concentrate the dielectric fluid 429 to the micropump 413, which is further aided by the casing inlet 431 being positioned at a same height and adjacent to the micropump inlet 415. Due to the micropump 413 being positioned at a same height of the casing inlet 431 by the aid of positioning protrusions 439 that are integrally formed with and part of the casing 427, the casing 427 is further configured to arrange the micropump 413 at a height that allows the dielectric fluid 429 to flow in a linear fluid flow path 435 into the micropump 413. Thus, overall, the casing 427 facilitates the circulation of the dielectric fluid 429 to baffles 423 of a heatsink 421 by virtue of directing the dielectric fluid 429 to the micropump 413 with the casing inlet 431 and redirecting the dielectric fluid 429 within the casing 427 itself.

In juxtaposition to the embodiment of the immersion cooling device 325 depicted in FIG. 3, the immersion cooling device 425 depicted in FIG. 4 is formed with a conduit including a manifold 451. More specifically, the manifold 451 is a conduit including a series a branches that are fluidly connected to the micropump outlet 417 of the micropump 413. The series of branches each extend to separate heatsinks 421 within the immersion cooling device 425, such that each branch of the manifold 451 forms a fluid flow path 435 between the micropump 413 and a particular heatsink 421. The heatsinks 421 are each removably attached to a separate electronic component 411 by way of a detachable mount 445, which may be embodied as a clamp, clip, or adhesive layer, for example, as discussed above. That is, the immersion cooling device 425 includes a plurality of electronic components 411 and a plurality of corresponding heatsinks 421, wherein each heatsink 421 of the plurality of heatsinks 421 is removably attached to one electronic component 411 of the plurality of electronic components 411.

However, and as depicted in FIG. 4, the electronic components 411 each have a different height. While the electronic components may have a same or similar height, it is often the case that certain electronic components (e.g., vertically positioned Random Access Memory (RAM) modules) will have a greater height than other electronic components (e.g., a Central Processing Unit (CPU)) that are positioned to substantially extend in a horizontal plane. Thus, to accommodate for the potential differences in the heights of two electronic components 411, the manifold 451 is formed in such a way that the series of branches each extend to different heights as well. Such is depicted in FIG. 4, where an upper branch of the manifold 451 extends in a substantially linear direction from the micropump 413 to a first heatsink 421, while a lower branch of the manifold 451 routes downward from the upper branch to connect to a second heatsink 421. In this way, the manifold 451 is configured to deliver dielectric fluid 429 to the specific height of each heat generating electronic component 411 within the immersion cooling device 425.

As further depicted in FIG. 4, each heatsink 421 is connected to a second conduit 420 that extends from a particular heatsink 421 to a casing outlet 433 of the casing 427. Thus, after the dielectric fluid 429 passes through the baffles 423 of each of the heatsinks 421, the second conduits 420 deliver the dielectric fluid 429 to the casing outlet 433. This allows the dielectric fluid 429 to exit the casing 427 entirely, at which point the dielectric fluid 429 may re-enter the casing 427 by way of the casing inlet 431, or be passed to an additional cooling circuit or device as described above.

Other embodiments of the invention that follow similar design principles may be envisaged without departing from the nature of this disclosure. For example, a manifold 451 may be formed as a single conduit with multiple heatsinks 421 disposed in series. In this case, the dielectric fluid 429 will flow through a first heatsink 421, absorb heat from a first electronic component 411, and subsequently flow through a second heatsink 421 to absorb heat from a second heat generating electronic component 411 before exiting the casing 427. Such a design may be advantageous, for example, when the second heat generating electronic component 411 is capable of accepting the hot output dielectric fluid 429 of the first heat generating electronic component 411 as a cold input to its corresponding second heatsink 421.

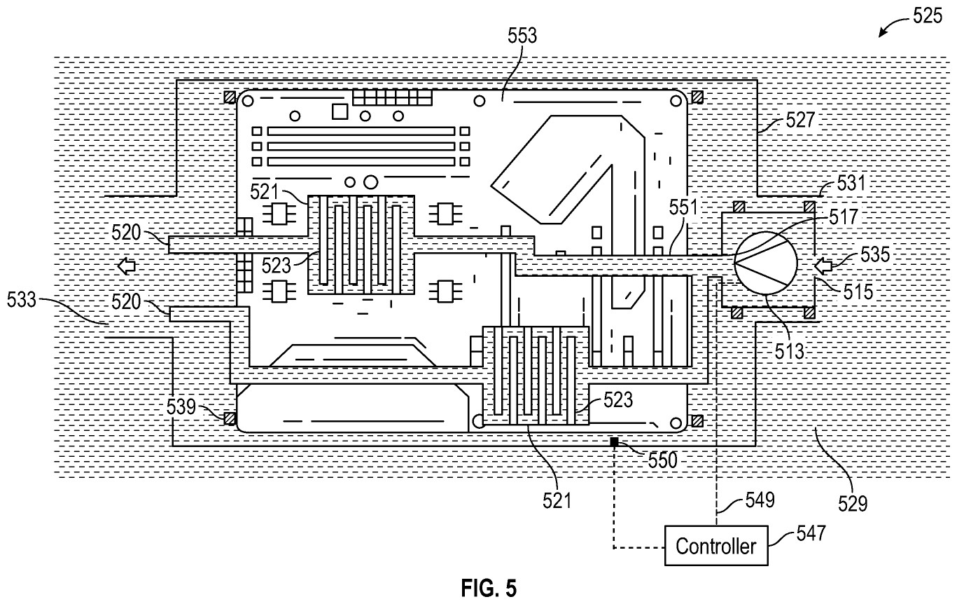

Turning to FIG. 5, FIG. 5 depicts an immersion cooling device 525 in accordance with one or more embodiments of the invention as described herein. As depicted in FIG. 5, the immersion cooling device 525 includes a casing 527 that is configured to protect and enshroud a circuit board 553. The circuit board 553 is formed as a printed circuit board, for example, that retains electrically powered elements on its uppermost surface that are interconnected by a conductive layer. In the case of FIG. 5, the circuit board 553 provides one example of an electronic system comprising a plurality of electronic components as described herein. The electronic components of the circuit board 553 are disposed below heatsinks 521, which serve to direct a volume of a dielectric fluid 529, such as mineral oil, in successive passes over the top of the electronic components. As the dielectric fluid 529 is passing over the electronic component, the dielectric fluid 529 absorbs heat generated by the electronic component, and carries the heat away from the electronic component and out of the casing 527 entirely.

To generate a fluid flow path 535 of the dielectric fluid 529, the immersion cooling device 525 includes a micropump 513. The micropump 513 includes a micropump inlet 515 that is formed as an orifice that receives the dielectric fluid 529 from a casing inlet 531 of the casing 527. In addition, the micropump 513 is retained in a lateral direction by way of positioning protrusions 539 that are integrally formed with the casing 527. An impeller (not shown) of the micropump 513 is actuated according to instructions, or operating commands, provided by a controller 547 based upon a temperature of the electronic components as discussed above. The controller 547 is connected to a data cable 549 embodied as a wire that is routed through a sidewall of the casing 527 or the casing inlet 531.

In addition, the controller 547 may be electrically connected by way of a data cable 549 to a temperature sensor 550 (e.g., a thermistor, a thermocouple, or a thermopile, for example), that determines the temperature of the dielectric fluid 529. The temperature sensor 550 may be adhered to or retained by/in the casing 527, or alternatively positioned adjacent to an electronic component or the circuit board 553. In addition, multiple temperature sensors 550 may be positioned within the casing in order to provide the controller 547 with measurements for each electronic component. The temperature sensor 550 provides the temperature of the dielectric fluid 529 (or electronic component(s) if positioned thereby) to the controller 547, at which point the controller 547 determines an operating command to issue to the micropump 513 as discussed above. When actuated, the micropump 513 draws dielectric fluid 529 into the casing inlet 531 and the micropump inlet 515. Subsequently, the micropump 513 expels the dielectric fluid 529 through a micropump outlet 517 into a manifold 551, where the micropump outlet 517 is formed as an orifice of the micropump 513 similar to the micropump inlet 515.

As depicted in FIG. 5, the manifold 551 is embodied as a conduit with a series of branches that serve to direct the dielectric fluid 529 to various locations within the casing 527. The various locations are more specifically the locations of the heatsinks 521, which are positioned immediately above and detachably fixed to electronic components of the circuit board 553 that generate a high heat load, or a heat load above a predetermined threshold. Because the electronic components may have different lateral positions on the circuit board 553, the heatsinks 521 are spaced apart in a lateral direction as well. The different lateral positions may be a function of the circuit board 553 design itself, where heatsinks 521 are disposed atop electronic components that create a “hotspot” of the circuit board 553. Alternatively, in the event that the electronic components are not attached to each other (e.g., FIG. 4), the electronic components may be spaced apart to prevent heat generated by a first electronic component from affecting a second electronic component, or to more generally prevent a first heat load from compounding with additional heat loads within the casing 527.

In conjunction with the above description in relation to FIG. 4 that electronic components may have varying heights, the manifold 551 is formed with a series of branches that deliver dielectric fluid 529 to a plurality of locations that are separated in up to three dimensions from each other. By way of example, a first electronic component on the circuit board 553 positioned below a first heatsink 521 may be in front of or behind, above or below, and/or to the right or left of a second electronic component positioned below a second heatsink 521. In this way, the manifold 551 is configured to specifically position a portion of the dielectric fluid 529 above the exact location of an electronic component.

Once the dielectric fluid 529 has passed through a branch of the manifold 551 and into a heatsink 521, the dielectric fluid 529 winds through baffles 523. The baffles 523 are formed as projections of the heatsinks 521 that serve to elongate the fluid flow path 535 of the dielectric fluid 529 over a particular electronic component. That is, the baffles 523 the heatsinks 521 are oriented such that a fluid flow path 535 of the dielectric fluid 529 is directed to wind in successive passes within the heatsinks 521 and above the electronic component detachably fixed thereto. This, in turn, increases the amount of time for the dielectric fluid 529 to absorb heat from the electronic component, and thus increases the amount of heat absorbed from the electronic component as a whole. Each heatsink 521 is connected, at its outlet, to a second conduit 520 that delivers the dielectric fluid 529 to a casing outlet 533 that forms an exit orifice of the casing 527. Thus, the second conduit 520 may extend in three dimensions through the casing 527 in a similar fashion as the manifold 551 in order to adapt from the particular location of a heatsink 521 to the location of the casing outlet 533. In this way, the immersion cooling device 525 is configured as a whole to deliver dielectric fluid 529 to the precise location of an electronic component contained therein.

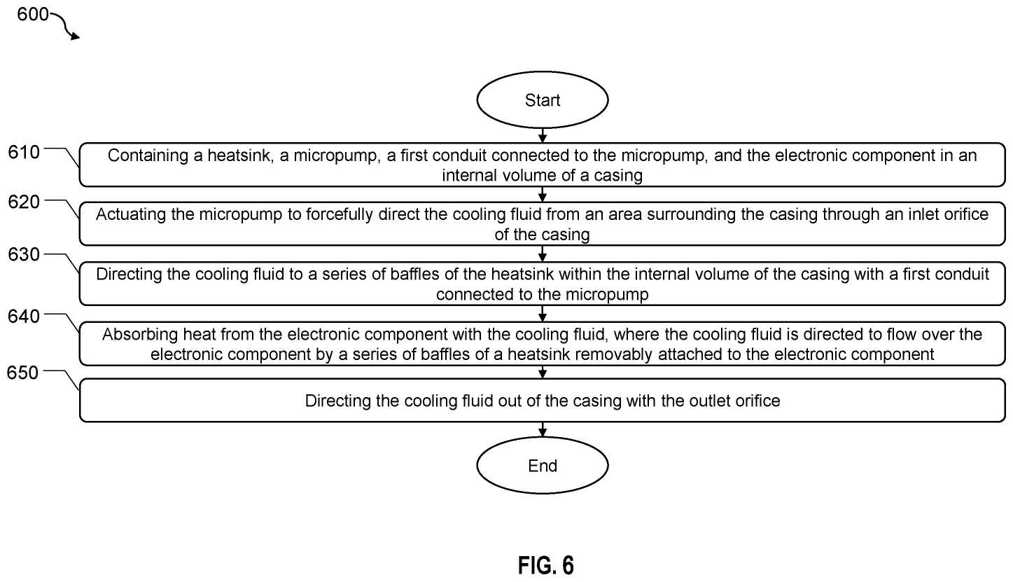

Turning to FIG. 6, FIG. 6 depicts a method 600 for cooling an electronic component in a cooling fluid immersion environment consistent with one or more embodiments described herein. Steps of FIG. 6 may be performed by an immersion cooling device as discussed above in relation to FIGS. 2-5, but are not limited thereto. Furthermore, the steps of FIG. 6 may be performed in any order, such that the steps are not limited to the sequence presented. In addition, multiple steps of FIG. 6 may be performed as a single action, or one step may comprise multiple actions by devices or components described herein.

The method 600 initiates with step 610, where a heatsink, a micropump, a first conduit connected to the micropump, and the electronic component are contained in an internal volume of a casing. The casing includes an inlet orifice and an outlet orifice, respectively referred to as the “casing inlet” and the “casing outlet” herein. The casing inlet and the casing outlet are holes formed in a sidewall of the casing, and are each positioned at a same height of the casing. During operation, the internal volume of the casing serves to house a volume of fluid that may be static or semi static (i.e., low velocity flow) and dissipates heat away from the electronic component and the heatsink. In addition, and as further discussed in relation to steps 620-640, the micropump creates a dynamic fluid flow within the casing that absorbs heat from the electronic component and actively removes the absorbed heat from the immersion cooling device entirely.

Step 620 comprises actuating a micropump to forcefully direct the cooling fluid. In particular, when the micropump is actuated, the micropump draws cooling fluid from its surroundings and passes the fluid to the conduit connected to the heatsink. The cooling fluid pulled into the micropump may be fluid already disposed within the casing, or the cooling fluid may be pulled through the casing inlet. That is, the cooling fluid is drawn from an area surrounding the components depicted in FIG. 1. Subsequently, the cooling fluid is forced through the heatsink, as discussed below in relation to step 630.

Step 630 includes directing the cooling fluid to a series of baffles of the heatsink within the internal volume of the casing. Once the cooling fluid enters the micropump from the cooling inlet, the cooling fluid is accelerated by the micropump and forced into a first conduit connected to an outlet of the micropump. The first conduit is formed as a tube that is connected to the micropump, such that the first conduit forms a fluid communication path between the micropump and the heatsink. Once the cooling fluid is forced through the first conduit by the micropump such that the cooling fluid enters the heatsink, the method proceeds to step 640.

Step 640 includes absorbing heat from an electronic component with a cooling fluid, such as dielectric fluid. More specifically, the cooling fluid is directed to flow from the entrance of the heatsink over the electronic component by a series of baffles of a heatsink. The heatsink is removably attached to the electronic component by way of a detachable mount, which may be embodied, for example, as a clip, a clamp, a bracket, an adhesive layer, a combination thereof, or other adherence mechanisms as would be appreciated by a person having ordinary skill in the art. The series of baffles create a winding fluid flow path of the dielectric fluid within the heatsink, which causes the dielectric fluid to flow in successive passes above the electronic component. Thus, the fluid flow path of the dielectric fluid is elongated over the electronic component, allowing the dielectric fluid additional time to absorb heat from the electronic component. Once the cooling fluid has been forced through the series of baffles of the heatsink, the method proceeds to step 650.

In step 650, the cooling fluid is directed out of the casing with an outlet orifice of the casing. In particular, and as discussed above, a second conduit extends from the outlet of the heatsink to the outlet orifice of the casing. Thus, after the cooling fluid has passed through the series of baffles of the heatsink, the cooling fluid is directed by the second conduit to the outlet orifice. At this point, backpressure developed by the micropump causes the cooling fluid to exit the casing entirely. Subsequently, the cooling fluid may re-enter the device by entering the inlet orifice of the casing, or may be directed to a second cooling device or system. In this way, the immersion cooling device generates a fluid flow of a cooling fluid that absorbs heat from an electronic component, and passes the fluid flow over the electronic component and away therefrom without recirculating within the immersion cooling device.

Although only a few example embodiments have been described in detail above, those skilled in the art will readily appreciate that many modifications are possible in the example embodiments without materially departing from this invention. For example, although the disclosure describes the use of a single micropump connected to a conduit or manifold, additional micropumps (each connected to an additional conduit or manifold) may be positioned within the casing to increase the cooling fluid flow rate or create additional cooling fluid flows. Furthermore, the micropump and the controller may be connected to an uninterruptible power supply or a backup power supply such that the immersion cooling device remains operable even if the electronic component is not powered. Alternatively, the micropump and the controller may be integrated with and powered by the electronic component itself in order to compact the design of the immersion cooling device. In addition, many modifications will be appreciated by those skilled in the art to adapt a particular instrument, situation, or material to embodiments of the disclosure without departing from the essential scope thereof. Thus, all such modifications are intended to be included within the scope of this disclosure.

Embodiments of the present disclosure may provide at least one of the following advantages: precise delivery of a cooling fluid to the exact location of an electronic component, and an increased amount of heat removed from an electronic component. Precise delivery of the cooling fluid is received by using conduits within the immersion cooling device to route the cooling fluid to the location of the upper side of the electronic component. Similarly, the amount of heat removed from the electronic component is increased as a function of elongating the fluid flow path of the cooling fluid above the electronic component such that the cooling fluid is provided with additional time to absorb heat from the electronic component. Furthermore, using ambient dielectric fluid that flows freely through a casing inlet and a casing outlet to cool an electronic component provides a reduced manufacturing complexity and cost.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A device for cooling an electronic component in a cooling fluid immersion environment, the device comprising:
a heatsink removably attached to the electronic component, wherein the heatsink comprises a series of baffles configured to direct the cooling fluid to flow over the electronic component, where the cooling fluid absorbs heat from the electronic component;
a casing comprising: an internal volume containing the heatsink and the electronic component, and an inlet orifice and an outlet orifice;
a micropump configured to actuate in order to forcefully direct the cooling fluid from an area surrounding the device, through the inlet orifice, through the series of baffles of the heatsink, and out of the outlet orifice of the casing; and
a first conduit, connected to the micropump, configured to direct the cooling fluid to the series of baffles of the heatsink within the internal volume of the casing.

2. The device of claim 1, wherein the micropump is disposed within the internal volume of the casing.

3. The device of claim 1, wherein the heatsink is formed as an enclosed structure comprising a heatsink inlet and a heatsink outlet.

4. The device of claim 1, wherein the first conduit comprises a manifold including a series of branches configured to connect the micropump to a plurality of heatsinks within the internal volume of the casing such that the cooling fluid is directed from the micropump to the plurality of heatsinks.

5. The device of claim 4, further comprising: a plurality of electronic components disposed in the internal volume of the casing, wherein each heatsink of the plurality of heatsinks is removably attached to one electronic component of the plurality of electronic components.

6. The device of claim 5, wherein a first heatsink of the plurality of heatsinks is disposed at a first height within the internal volume of the casing, and a second heatsink of the plurality of heatsinks is disposed at a second height, different from the first height, within the internal volume of the casing, where a height of the casing is measured in a direction orthogonal to a primary extension direction of the casing.

7. The device of claim 1, further comprising: a second conduit connected to the heatsink, the second conduit being configured to direct the cooling fluid from the heatsink to the outlet orifice of the casing.

8. The device of claim 1, wherein the inlet orifice and the outlet orifice are positioned at a same height of the casing, where a height of the casing is measured in a direction orthogonal to a primary extension direction of the casing.

9. The device of claim 1, wherein the baffles of the heatsink are oriented such that a fluid flow path of the cooling fluid is directed to wind in successive passes within the heatsink and above the electronic component.

10. The device of claim 1, wherein the micropump is separated in a horizontal direction from the inlet orifice of the casing such that a gap exists between the micropump and the inlet orifice, the gap being configured to direct a portion of the cooling fluid to enter the internal volume of the casing such that the micropump, the first conduit, the heatsink, and the electronic component are immersed in the cooling fluid within the internal volume of the casing.

11. A method for cooling an electronic component in a cooling fluid immersion environment, the method comprising:
containing a heatsink, a micropump, a first conduit connected to the micropump, and the electronic component in an internal volume of a casing, where the casing comprises an inlet orifice and an outlet orifice;
actuating the micropump to forcefully direct the cooling fluid from an area surrounding the casing through the inlet orifice;
directing the cooling fluid to a series of baffles of the heatsink within the internal volume of the casing with the first conduit connected to the micropump;
absorbing heat from the electronic component with the cooling fluid, where the cooling fluid is directed to flow over the electronic component by the series of baffles of the heatsink removably attached to the electronic component, and
directing the cooling fluid out of the casing with the outlet orifice.

12. The method of claim 11, further comprising: positioning the micropump within the internal volume of the casing.

13. The method of claim 11, further comprising: forming the heatsink as an enclosed structure comprising a heatsink inlet and a heatsink outlet.

14. The method of claim 11, wherein the first conduit comprises a manifold including a series of branches, and the method further comprises: connecting the micropump to a plurality of heatsinks within the internal volume of the casing with the series of branches of the manifold such that the cooling fluid is directed from the micropump to the plurality of heatsinks.

15. The method of claim 14, further comprising: removably attaching each heatsink of the plurality of heatsinks to one electronic component of a plurality of electronic components disposed in the internal volume of the casing.

16. The method of claim 15, further comprising: positioning a first heatsink of the plurality of heatsinks at a first height within the internal volume of the casing, and positioning a second heatsink of the plurality of heatsinks at a second height, different from the first height, within the internal volume of the casing, where a height of the casing is measured in a direction orthogonal to a primary extension direction of the casing.

17. The method of claim 11, further comprising: directing the cooling fluid from the heatsink to the outlet orifice of the casing with a second conduit.

18. The method of claim 11, further comprising: positioning the inlet orifice and the outlet orifice at a same height of the casing, where a height of the casing is measured in a direction orthogonal to a primary extension direction of the casing.

19. The method of claim 11, further comprising: directing a fluid flow path of the cooling fluid with the series of baffles of the heatsink to wind in successive passes within the heatsink and above the electronic component.

20. The method of claim 11, further comprising: directing a portion of the cooling fluid to enter the internal volume of the casing by way of a gap between the micropump and the inlet orifice such that the micropump, the first conduit, the heatsink, and the electronic component are immersed in the cooling fluid within the internal volume of the casing.
